(19) United States
(12) Patent Application Publication
(10) Pub. No.: US 2025/0210577 A1
(43) Pub. Date: Jun. 26, 2025

(54) SEMICONDUCTOR DEVICE AND METHOD OF MANUFACTURING THE SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yutaro HAYASHI, Yokohama Kanagawa (JP); Hisashi TOMITA, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/078,794

(22) Filed: Mar. 13, 2025

Related U.S. Application Data
(63) Continuation of application No. PCT/JP2024/008602, filed on Mar. 6, 2024.

(30) Foreign Application Priority Data
Jul. 31, 2023 (JP) 2023-124783

(51) Int. Cl. H01L 23/00

(52) U.S. Cl. CPC H01L 24/32; H01L 24/29; H01L 24/83; H01L 2224/29111; H01L 2224/29116; H01L 2224/29139; H01L 2224/29144; H01L 2224/29147; H01L 2224/29155; H01L 2224/32059; H01L 2224/32245; H01L 2224/83201; H01L 2224/83439; H01L 2224/83444; H01L 2224/83447; H01L 2224/83455; H01L 2224/83457; H01L 2224/8346; H01L 2224/83464; H01L 2224/83476; H01L 2224/8348; H01L 2224/83484; H01L 2224/8384

(57) ABSTRACT

According to one embodiment, a semiconductor device includes a chip having a first surface and a second surface, a first electrode pad provided on the first surface of the chip, a first conductive layer provided above the first electrode pad, a first bonding material that is provided between the first electrode pad and the first conductive layer and is in contact with the first electrode pad and the first conductive layer, and a second electrode pad provided on the second surface of the chip. A third surface of the first bonding material facing the first electrode pad has a contact portion in contact with the first electrode pad and a notch portion surrounding the contact portion. An end of the contact portion is located inside an end surface of the first conductive layer.

### CROSS-REFERENCE TO RELATED APPLICATIONS

This application is a Continuation Application of PCT Application No. PCT/JP2024/008602, filed Mar. 6, 2024 and based upon and claiming the benefit of priority from Japanese Patent Application No. 2023-124783, filed Jul. 31, 2023, the entire contents of all of which are incorporated herein by reference.

### FIELD

Embodiments described herein relate generally to a semiconductor device and a method of manufacturing the semiconductor device.

### BACKGROUND

A semiconductor device having a structure in which a front surface and a back surface of a semiconductor chip are connected to a conductor via a bonding material is known.

### BRIEF DESCRIPTION OF THE DRAWINGS

FIG. 1 is a cross-sectional view illustrating an example of a structure of a semiconductor device according to a first embodiment.

FIG. 2 is a plan view illustrating an example of the structure of the semiconductor device according to the first embodiment.

FIG. 3 is a plan view illustrating an example of the structure of the semiconductor device according to the first embodiment.

FIG. 4 is a cross-sectional view illustrating an example of the structure of the semiconductor device according to the first embodiment.

FIG. 5 is a cross-sectional view illustrating an example of the structure of the semiconductor device according to the first embodiment.

FIG. 6 is a flowchart illustrating an example of a method of manufacturing the semiconductor device according to the first embodiment.

FIG. 7 is a cross-sectional view illustrating an example of a structure in a process of manufacturing the semiconductor device according to the first embodiment.

FIG. 8 is a cross-sectional view illustrating an example of the structure in the process of manufacturing the semiconductor device according to the first embodiment.

FIG. 9 is a plan view illustrating an example of the structure in the process of manufacturing the semiconductor device according to the first embodiment.

FIG. 10 is a cross-sectional view illustrating an example of the structure in the process of manufacturing the semiconductor device according to the first embodiment.

FIG. 11 is a cross-sectional view illustrating an example of the structure in the process of manufacturing the semiconductor device according to the first embodiment.

FIG. 12 is a cross-sectional view illustrating an example of the structure in the process of manufacturing the semiconductor device according to the first embodiment.

FIG. 13 is a cross-sectional view illustrating an example of the structure in the process of manufacturing the semiconductor device according to the first embodiment.

FIG. 14 is an enlarged cross-sectional view illustrating a part of the structure of the semiconductor device according to the first embodiment.

FIG. 15 is a flowchart illustrating an example of a method of manufacturing a semiconductor device according to a modification of the first embodiment.

FIG. 16 is a plan view illustrating an example of a structure in a process of manufacturing the semiconductor device according to the modification of the first embodiment.

FIG. 17 is a plan view illustrating an example of a structure of a semiconductor device according to a second embodiment.

FIG. 18 is a cross-sectional view illustrating an example of the structure of the semiconductor device according to the second embodiment.

FIG. 19 is a cross-sectional view illustrating an example of the structure of the semiconductor device according to the second embodiment.

FIG. 20 is a flowchart illustrating an example of a method of manufacturing the semiconductor device according to the second embodiment.

FIG. 21 is an enlarged cross-sectional view illustrating a part of the structure of the semiconductor device according to the second embodiment.

### DETAILED DESCRIPTION

In general, according to one embodiment, a semiconductor device includes a chip having a first surface and a second surface opposite to the first surface, a first electrode pad provided on the first surface of the chip, a first conductive layer provided above the first electrode pad, a first bonding material that is provided between the first electrode pad and the first conductive layer and is in contact with the first electrode pad and the first conductive layer, and a second electrode pad provided on the second surface of the chip. A third surface of the first bonding material facing the first electrode pad has a contact portion in contact with the first electrode pad and a notch portion surrounding the contact portion. An end of the contact portion is located inside an end surface of the first conductive layer.

Hereinafter, embodiments will be described with reference to the drawings. Dimensions and ratios in the drawings are not necessarily the same as actual dimensions and ratios. In the following description, components having substantially the same functions and configurations are denoted by the same reference signs, and repeated description may be omitted. In a case where components having similar configurations are particularly distinguished from each other, different characters or numbers may be added to the end of the same reference sign. All descriptions about one embodiment also apply as descriptions about another embodiment unless expressly or explicitly excluded.

### 1. FIRST EMBODIMENT

A semiconductor device according to a first embodiment will be described.

### 1.1 Structure of Semiconductor Device

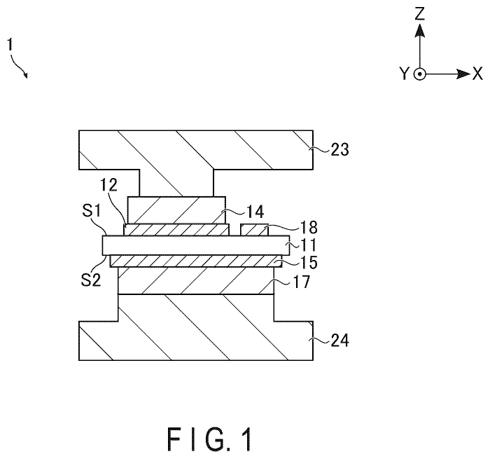

A structure of the semiconductor device will be described with reference to FIG. 1. FIG. 1 is a cross-sectional view illustrating an example of the structure of the semiconductor device.

As illustrated in FIG. 1, the semiconductor device 1 includes a semiconductor chip 11, a first electrode pad 12, a first conductive layer 14, a second electrode pad 15, a second conductive layer 17, a third electrode pad 18, a first electrode 23, and a second electrode 24. Hereinafter, the semiconductor chip 11 is simply referred to as a “chip 11”. Although not illustrated in FIG. 1, the semiconductor device 1 includes a gate terminal plate (not illustrated). The gate terminal plate is connected to the third electrode pad 18 via a spring pin (not illustrated), for example.

The chip 11 is a power semiconductor chip. Specifically, for example, the chip 11 is an injection enhanced gate transistor (IEGT), an insulated gate bipolar transistor (IGBT), or a field effect transistor (Metal-Oxide-Silicon Field-Effect Transistor (MOS FET)) using silicon carbide (SiC). A case where the chip 11 is an IEGT will be described below as an example.

The chip 11 has a first surface S1 and a second surface S2 opposite to the first surface S1. Hereinafter, a plane parallel to the first surface S1 and the second surface S2 is defined as an XY plane. Directions perpendicular to each other on the XY plane are defined as an X direction and a Y direction. A direction substantially perpendicular to the XY plane is defined as a Z direction. The first surface S1 is also referred to as a front surface of the chip 11. The second surface S2 is also referred to as a back surface of the chip 11.

The first electrode pad 12 is an emitter electrode pad. The first electrode pad 12 is electrically connected to an emitter electrode (not illustrated) of the chip 11. The first electrode pad 12 is provided on the first surface S1 of the chip 11. The first electrode pad 12 is formed of a conductive material.

The first conductive layer 14 is a conductor that electrically connects the first electrode pad 12 and the first electrode 23. The first conductive layer 14 is provided above the first electrode pad 12 on the front surface side of the chip 11. The first conductive layer 14 is bonded to the first electrode pad 12 via a bonding material (not illustrated). Specifically, the first conductive layer 14 is uniformly in pressure contact with the first electrode pad 12 via the bonding material. The first conductive layer 14 is formed of a conductive material, and includes, for example, any of molybdenum, ruthenium, tungsten, iron, gold, silver, copper, cobalt, nickel, and palladium.

The second electrode pad 15 is a collector electrode pad. The second electrode pad 15 is electrically connected to a collector electrode (not illustrated) of the chip 11. The second electrode pad 15 is provided on the second surface S2 of the chip 11. The second electrode pad 15 is formed of a conductive material.

The second conductive layer 17 is a conductor that electrically connects the second electrode pad 15 and the second electrode 24. The second conductive layer 17 is provided above the second electrode pad 15 on the back surface side of the chip 11. The second conductive layer 17 is bonded to the second electrode pad 15 via a bonding material (not illustrated). Specifically, the second conductive layer 17 is uniformly in pressure contact with the second electrode pad 15 via the bonding material. The second conductive layer 17 is formed of a conductive material, and includes, for example, any of molybdenum, ruthenium, tungsten, iron, gold, silver, copper, cobalt, nickel, and palladium.

The third electrode pad 18 is a gate electrode pad. The third electrode pad 18 is provided on the first surface S1 of the chip 11 while being spaced apart from the first electrode pad 12. The third electrode pad 18 is formed of a conductive material.

The first electrode 23 is an electrode for supplying a voltage to the emitter electrode of the chip 11. The first electrode 23 is provided on the first conductive layer 14 on the front surface side of the chip 11. The first electrode 23 is in pressure contact with the emitter electrode of the chip 11 via the first conductive layer 14 and the first electrode pad 12. The first electrode 23 is formed of a conductive material such as copper, nickel, or the like.

The second electrode 24 is an electrode for supplying a voltage to the collector electrode of the chip 11. The second electrode 24 is provided on the second conductive layer 17 on the back surface side of the chip 11. The second electrode 24 is in pressure contact with the collector electrode of the chip 11 via the second conductive layer 17 and the second electrode pad 15. The second electrode 24 is formed of a conductive material such as copper, nickel, or the like.

An insulating film (not illustrated) is provided on an outer peripheral portion (outer peripheral portion of each of the first electrode pad 12, a first bonding material 13 (described later), the first conductive layer 14, the second electrode pad 15, a second bonding material 16 (described later), the second conductive layer 17, the third electrode pad 18, the first electrode 23, and the second electrode 24) of the semiconductor device 1.

The semiconductor device 1 is used, for example, in a press pack IEGT (PPI). The PPI includes a plurality of chips 11 arranged on the same XY plane. The first electrode pad 12 provided on the front surface of each of the chips 11 is pressed and bonded by the first conductive layer 14. The second electrode pad 15 provided on the back surface of each of the chips 11 is pressed and bonded by the second conductive layer 17. The first conductive layer 14 connected to each of the chips 11 is pressed and bonded by, for example, one first electrode 23. The second conductive layer 17 connected to each of the chips 11 is pressed and bonded by, for example, one second electrode 24. A space surrounded by the chip 11, the first electrode pad 12, the first conductive layer 14, the second electrode pad 15, the second conductive layer 17, the third electrode pad 18, the first electrode 23, and the second electrode 24 is filled with resin, thereby sealing the chip 11, the first electrode pad 12, the first conductive layer 14, the second electrode pad 15, the second conductive layer 17, and the third electrode pad 18.

In a case where the chip 11 is a MOSFET using SiC, the first electrode pad 12 corresponds to a source electrode pad. The second electrode pad 15 corresponds to a drain electrode pad. The emitter electrode of the chip 11 corresponds to a source electrode of the chip 11. The collector electrode of the chip 11 corresponds to a drain electrode of the chip 11.

### 1.1.1 Planar Structure of Semiconductor Device

A planar structure of the semiconductor device 1 will be described.

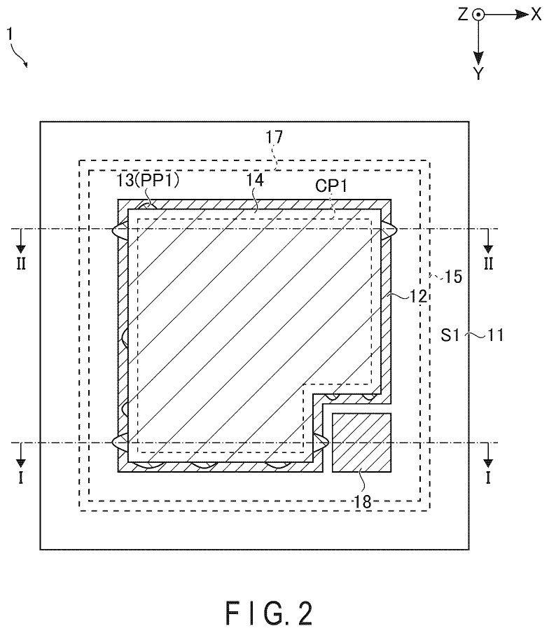

FIG. 2 is a plan view illustrating an example of the structure of the semiconductor device 1. FIG. 2 is a plan view of the semiconductor device 1 as viewed from the first surface S1 side of the chip 11. The chip 11, the first electrode pad 12, the first bonding material 13, the first conductive layer 14, and the third electrode pad 18 are indicated by solid lines. The second electrode pad 15 and the second conductive layer 17 are indicated by broken lines. In FIG. 2, illustration of the first electrode 23 and the second electrode 24 is omitted.

As illustrated in FIG. 2, the semiconductor device 1 further includes the first bonding material 13 in addition to the configuration illustrated in FIG. 1.

The first electrode pad 12 is provided on the first surface S1 of the chip 11. The first electrode pad 12 has, for example, a substantially L-shape in top view (as viewed from the upper side of the drawing).

The first bonding material 13 is a member for bonding the first electrode pad 12 and the first conductive layer 14. The first bonding material 13 is provided on the first electrode pad 12. The first bonding material 13 has a contact portion CP1 in contact with the first electrode pad 12 and a notch portion NP (not illustrated in FIG. 2) provided to surround the contact portion CP1. In other words, the notch portion NP is a portion not in contact with the first electrode pad 12. The end of the contact portion CP1 is located inside an end surface (side surface) of the first conductive layer 14.

In addition, the first bonding material 13 has a portion extending outward from the end surface of the first conductive layer 14. In other words, the first bonding material 13 has a projecting portion which projects outward from the end surface of the first conductive layer 14. Hereinafter, the projecting portion is referred to as a “projecting portion PP1”. The projecting portion PP1 is a portion protruding outward from the end surface of the first conductive layer 14 by pressurizing and sintering the first conductive layer 14 to which the first bonding material 13 has been transferred on the first electrode pad 12 in a manufacturing method described later. The projecting portion PP1 is provided on at least a part of the first bonding material 13.

FIG. 2 illustrates an example in which a plurality of projecting portions PPI are separated from each other. All of the plurality of projecting portions PP1 may be in contact with each other. That is, the plurality of projecting portions PP1 may be integrated. In addition, the amounts of the protrusions of the first bonding material 13 protruding outward from the end surface of the first conductive layer 14 may differ depending on the positions.

The first bonding material 13 is formed of a conductive material, and includes, for example, any of gold, silver, copper, lead, tin, and nickel.

The first conductive layer 14 is provided on the first bonding material 13. The first conductive layer 14 has, for example, a substantially L-shape in top view. The first conductive layer 14 is smaller in size than the first electrode pad 12. In other words, the end surface of the first conductive layer 14 is located inside an end surface (side surface) of the first electrode pad 12.

The third electrode pad 18 is provided on the first surface S1 of the chip 11. The third electrode pad 18 has, for example, a substantially rectangular shape in top view. The third electrode pad 18 is spaced apart from the first electrode pad 12 in the X direction and the Y direction.

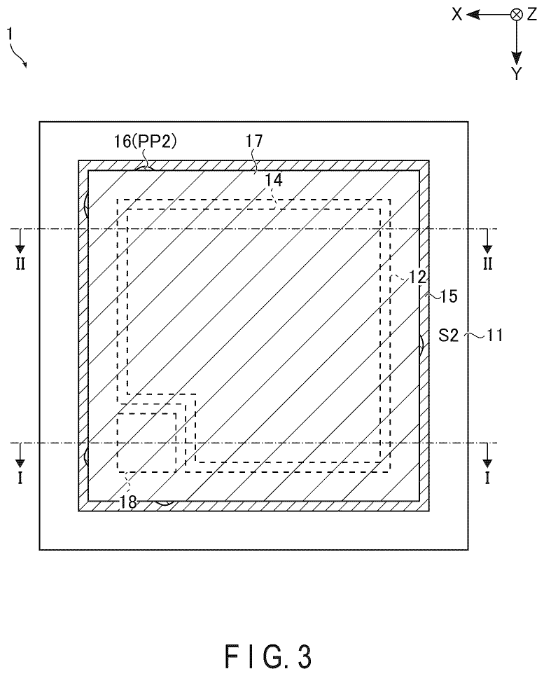

FIG. 3 is a plan view illustrating an example of the structure of the semiconductor device 1. FIG. 3 is a plan view of the semiconductor device 1 as viewed from the second surface S2 side of the chip 11. The chip 11, the second electrode pad 15, the second bonding material 16, and the second conductive layer 17 are indicated by solid lines. The first electrode pad 12, the first conductive layer 14, and the third electrode pad 18 are indicated by broken lines. In FIG. 3, illustration of the first electrode 23 and the second electrode 24 is omitted.

As illustrated in FIG. 3, the semiconductor device 1 further includes the second bonding material 16 in addition to the configuration illustrated in FIG. 1.

The second electrode pad 15 is provided on the second surface S2 of the chip 11. The second electrode pad 15 has, for example, a substantially rectangular shape in top view. The second electrode pad 15 is larger in size than the first electrode pad 12. This is because a current flowing from the second electrode pad 15 to the first electrode pad 12 is controlled within a relatively wide current value range. In a case where the size of the second electrode pad 15 is relatively small, the amount of charge supplied from the second electrode pad 15 to the first electrode pad 12 is relatively small. In this case, the current flowing from the second electrode pad 15 to the first electrode pad 12 is controlled within a relatively narrow current value range. Therefore, the size of the second electrode pad 15 is designed to be larger than the size of the first electrode pad 12.

The second bonding material 16 is a member for bonding the second electrode pad 15 and the second conductive layer 17. The second bonding material 16 is provided on the second electrode pad 15. The second bonding material 16 has a portion extending outward from an end surface (side surface) of the second conductive layer 17. In other words, the second bonding material 16 has a projecting portion which projects outward from the end surface of the second conductive layer 17. Hereinafter, the projecting portion is referred to as a “projecting portion PP2”. Similarly to the projecting portion PP1, the projecting portion PP2 is a portion protruding outward from the end surface of the second conductive layer 17 by pressurizing and sintering the second conductive layer 17 to which the second bonding material 16 has been transferred on the second electrode pad 15 in the manufacturing method described later. The projecting portion PP2 is provided on at least a part of the second bonding material 16.

FIG. 3 illustrates an example in which a plurality of projecting portions PP2 are separated from each other. All of the plurality of projecting portions PP2 may be in contact with each other. That is, the plurality of projecting portions PP2 may be integrated. In addition, the amounts of the protrusions of the second bonding material 16 protruding outward from the end surface of the second conductive layer 17 may differ depending on the positions.

In a case where the size of the electrode pad (the first electrode pad 12 or the second electrode pad 15) is relatively small, a load is likely to be applied in pressurization of the conductive layer (the first conductive layer 14 or the second conductive layer 17). Therefore, the amount of the protrusion of the bonding material (the first bonding material 13 or the second bonding material 16) protruding outward from the end surface of the conductive layer (the first conductive layer 14 or the second conductive layer 17) is larger in the first bonding material 13 pressurized by the first electrode pad 12 having a smaller size than in the second bonding material 16. That is, the amount of the protrusion of the projecting portion PP1 is larger than the amount of the protrusion of the projecting portion PP2.

The second bonding material 16 is formed of a conductive material, and includes, for example, any of gold, silver, copper, lead, tin, and nickel.

The second conductive layer 17 is provided on the second bonding material 16. The second conductive layer 17 has, for example, a substantially rectangular shape in top view. The second conductive layer 17 is smaller in size than the second electrode pad 15 and larger in size than the first electrode pad 12. In other words, the end surface of the second conductive layer 17 is located inside an end surface (side surface) of the second electrode pad 15 and is located outside the end surface of the first electrode pad 12.

### 1.1.2 Cross-Sectional Structure of Semiconductor Device

A cross-sectional structure of the semiconductor device 1 will be described.

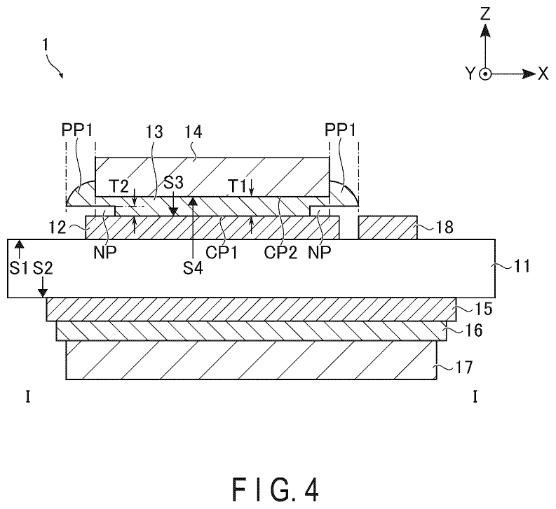

FIG. 4 is a cross-sectional view taken along line I-I in FIGS. 2 and 3, illustrating an example of the structure of the semiconductor device 1. In FIG. 4, illustration of the first electrode 23 and the second electrode 24 is omitted.

As illustrated in FIG. 4, the first electrode pad 12 is provided on the first surface S1 of the chip 11. The first bonding material 13 is provided on the first electrode pad 12. The first conductive layer 14 is provided on the first bonding material 13. In other words, the first bonding material 13 is provided between the first electrode pad 12 and the first conductive layer 14. The first bonding material 13 is in contact with the first electrode pad 12 and the first conductive layer 14. That is, the first bonding material 13 bonds the first electrode pad 12 and the first conductive layer 14.

A surface (hereinafter, referred to as a “third surface S3”) of the first bonding material 13, in which the surface faces the first electrode pad 12, has the contact portion CP1 in contact with the first electrode pad 12 and the notch portion NP provided to surround the contact portion CP1. The end of the contact portion CP1 is located inside the end surface of the first conductive layer 14.

By providing the notch portion NP on the third surface S3 of the first bonding material 13 so as to surround the contact portion CP1, the surface area of the first bonding material 13 is increased by the area of the surface of the notch portion NP, in which the surface faces the first electrode pad 12, as compared with a case where the notch portion NP is not provided on the third surface S3 of the first bonding material 13. That is, the surface area of the first bonding material 13 is increased as compared with a case where the entire third surface S3 of the first bonding material 13 is the contact portion CP1. Therefore, the heat dissipation of the first bonding material 13 is improved.

The first bonding material 13 has the projecting portion PP1 which projects outward from the end surface of the first conductive layer 14. The projecting portion PP1 of the first bonding material 13 is in contact with a part of the end surface of the first conductive layer 14.

Since the first bonding material 13 has the projecting portion PP1, the surface area of the first bonding material 13 is increased by the surface area of the projecting portion PP1 as compared with the case where the projecting portion PP1 is not provided. Therefore, the heat dissipation of the first bonding material 13 is improved. Additionally, in a case where the projecting portion PP1 is in contact with the part of the end surface of the first conductive layer 14, the surface area of the projecting portion PP1 is further increased. Therefore, the heat dissipation of the first bonding material 13 is further improved.

Furthermore, the end of the contact portion CP1 is located inside the end surface of the first electrode pad 12. The projecting portion PP1 of the first bonding material 13 is located above the first electrode pad 12 on the front surface side of the chip 11.

A surface (hereinafter, referred to as a “fourth surface S4”) of the first bonding material 13, in which the surface faces the first conductive layer 14, has a contact portion CP2 in contact with the first conductive layer 14. A thickness T1 of the first bonding material 13 at the contact portion CP1 (the thickness between the contact portion CP1 and the contact portion CP2) is preferably, for example, 5 μm to 80 μm.

A thickness T2 of the notch portion NP is preferably less than or equal to ½ of the thickness T1 of the first bonding material 13 at the contact portion CP1. In a case where the thickness T2 is greater than ½ of the thickness T1, for example, there is a possibility that the projecting portion PP1 may fall off during assembly of the PPI.

The third electrode pad 18 is provided on the first surface S1 of the chip 11. The third electrode pad 18 is spaced apart from the first electrode pad 12. Additionally, the third electrode pad 18 is spaced apart from the projecting portion PP1 of the first bonding material 13. That is, the third electrode pad 18 is not in contact with the projecting portion PP1 of the first bonding material 13.

The second electrode pad 15 is provided on the second surface S2 of the chip 11. The second bonding material 16 is provided on the second electrode pad 15. The second conductive layer 17 is provided on the second bonding material 16. In other words, the second bonding material 16 is provided between the second electrode pad 15 and the second conductive layer 17. The second bonding material 16 is in contact with the second electrode pad 15 and the second conductive layer 17. That is, the second bonding material 16 bonds the second electrode pad 15 and the second conductive layer 17.

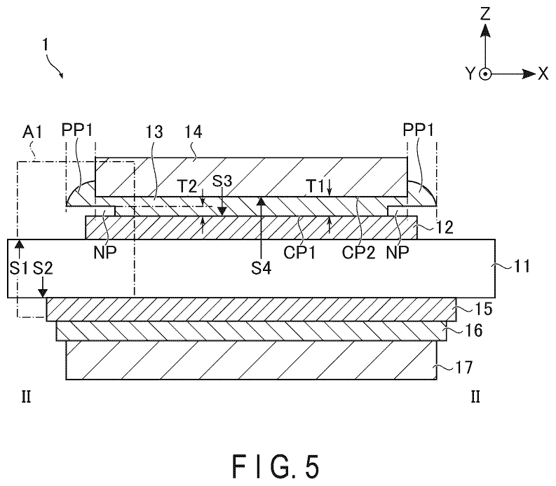

FIG. 5 is a cross-sectional view taken along line II-II in FIGS. 2 and 3, illustrating an example of the structure of the semiconductor device 1. In FIG. 5, illustration of the first electrode 23 and the second electrode 24 is omitted.

As illustrated in FIG. 5, the first electrode pad 12, the first bonding material 13, and the first conductive layer 14 provided on the front surface of the chip 11 are longer than the first electrode pad 12, the first bonding material 13, and the first conductive layer 14 illustrated in FIG. 4, respectively, in the X direction.

The structures of the first electrode pad 12, the first bonding material 13, and the first conductive layer 14 provided on the front surface of the chip 11 are similar to those in FIG. 4. The thickness T1 of the first bonding material 13 and the thickness T2 of the notch portion NP are also similar to those in FIG. 4. Therefore, the description of the structures of the first electrode pad 12, the first bonding material 13, and the first conductive layer 14, and the thickness T1 of the first bonding material 13 and the thickness T2 of the notch portion NP is omitted.

The structures of the second electrode pad 15, the second bonding material 16, and the second conductive layer 17 provided on the back surface of the chip 11 are similar to those in FIG. 4. Therefore, the description of the structures of the second electrode pad 15, the second bonding material 16, and the second conductive layer 17 is omitted.

Also in the cross section along the Y direction in FIGS. 2 and 3, the structures of the first electrode pad 12, the first bonding material 13, the first conductive layer 14, the second electrode pad 15, the second bonding material 16, the second conductive layer 17, and the third electrode pad 18 are similar to those in FIGS. 4 and 5. The thickness T1 of the first bonding material 13 and the thickness T2 of the notch portion NP are also similar to those in FIGS. 4 and 5.

### 1.2 Method of Manufacturing Semiconductor Device

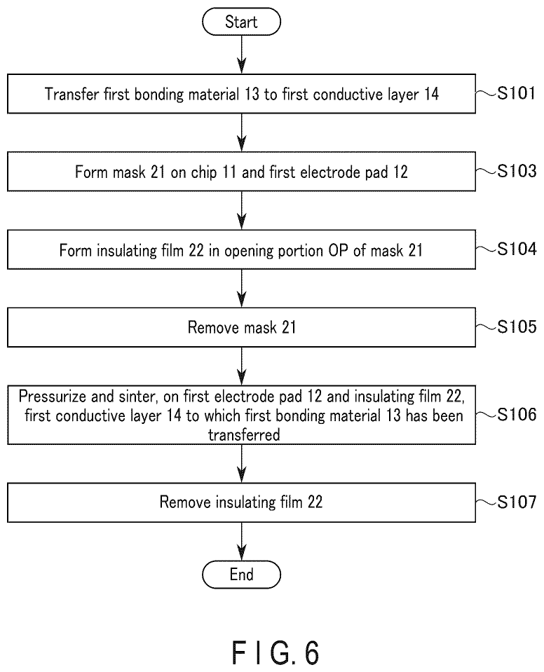

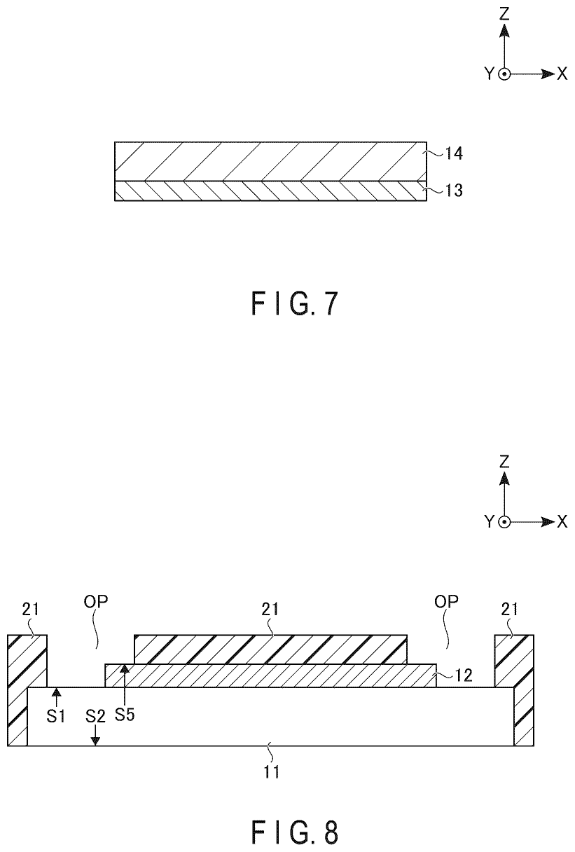

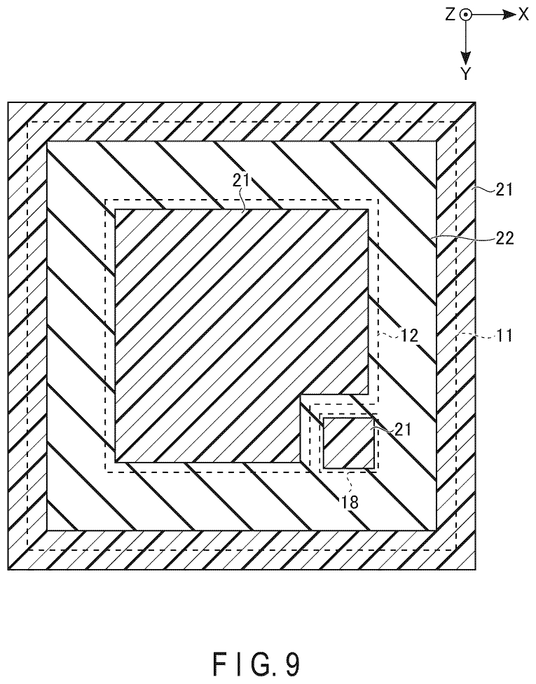

A method of manufacturing the semiconductor device 1 will be described with reference to FIGS. 6 to 13. FIG. 6 is a flowchart illustrating an example of a method of manufacturing the semiconductor device 1. Each of FIGS. 7, 8, and 10 to 13 is a cross-sectional view taken along line II-II in FIGS. 2 and 3, illustrating an example of a structure in a process of manufacturing the semiconductor device 1. FIG. 9 is a plan view illustrating an example of the structure in the process of manufacturing the semiconductor device 1. A process of forming the first electrode pad 12, the first bonding material 13, and the first conductive layer 14 on the first surface S1 of the chip 11 in the process of manufacturing the semiconductor device 1 will be described below. Therefore, in FIGS. 7 to 13, illustration of the second electrode pad 15, the second bonding material 16, the second conductive layer 17, the first electrode 23, and the second electrode 24 is omitted.

As illustrated in FIG. 6, in the process of manufacturing the semiconductor device 1, after the first electrode pad 12 is formed on the first surface S1 of the chip 11, processing in steps S101 and S103 to S107 is sequentially performed. An example of the process of manufacturing the semiconductor device 1 will be described below with reference to FIG. 6 as appropriate.

First, as illustrated in FIG. 7, the first bonding material 13 is transferred (bonded) to the first conductive layer 14 (S101).

Next, a mask 21 is formed on the chip 11 and the first electrode pad 12 (S103). The mask 21 is formed by, for example, photolithography.

Specifically, first, a photoresist is applied onto the chip 11 and the first electrode pad 12. Next, a photomask in which a portion where an insulating film 22 to be described later is to be provided is opened is prepared. Next, the chip 11 and the first electrode pad 12 are aligned with the photomask, and the photoresist is irradiated with and exposed to ultraviolet light. Next, the photoresist is developed. As a result, the mask 21 is formed. The mask 21 is also formed on the third electrode pad 18. As illustrated in FIG. 8, an opening portion OP is formed on an end portion of a surface (hereinafter, referred to as a “fifth surface S5”) of the first electrode pad 12, in which the surface is opposite to the chip 11, and a part of the chip 11.

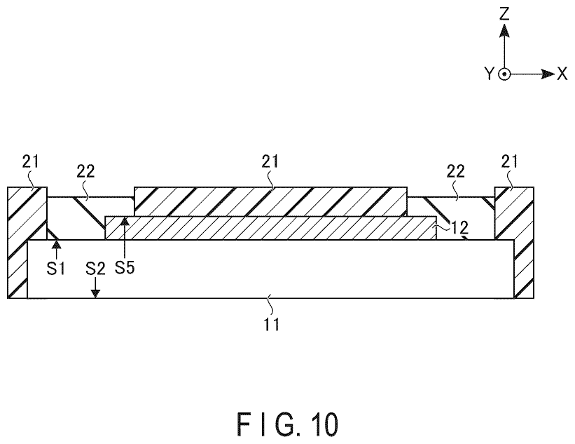

Next, as illustrated in FIGS. 9 and 10, the insulating film 22 is formed in the opening portion OP of the mask 21 (S104). The insulating film 22 is formed by, for example, a vacuum vapor deposition method, a sputtering method, a CVD method, or the like. The insulating film 22 is, for example, a material (resin such as propylene carbonate, polypropylene carbonate, or the like) that has heat resistance and low thermal decomposability and can be cleaned, or a material (polyurethane resin or the like) having high thermal decomposability. As illustrated in FIG. 9, the insulating film 22 is formed so as to cover an end portion of the first electrode pad 12 and a part of the chip 11 and to surround the first electrode pad 12 and the third electrode pad 18. As illustrated in FIG. 10, the insulating film 22 is formed so as to cover the end surface of the first electrode pad 12, the end portion of the fifth surface S5 of the first electrode pad 12, and the part of the chip 11. The end portion of the fifth surface S5 of the first electrode pad 12 means not only the end of the fifth surface S5 but also a region from the end of the fifth surface S5 to an end surface of the mask 21 provided on the first electrode pad 12.

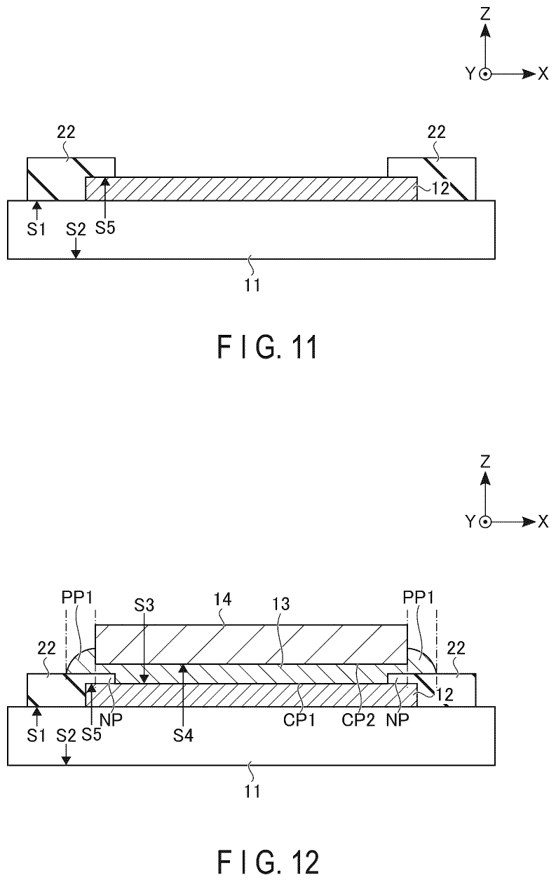

Next, as illustrated in FIG. 11, the mask 21 is removed (S105). The mask 21 is removed by, for example, a peeling solution.

Next, as illustrated in FIG. 12, the first conductive layer 14 to which the first bonding material 13 has been transferred is pressurized and sintered on the first electrode pad 12 and the insulating film 22 (S106). As a result, the first bonding material 13 is pressurized, and the contact portion CP1 and the notch portion NP are formed on the third surface S3 of the first bonding material 13. The projecting portion PP1 of the first bonding material 13 is formed on the insulating film 22.

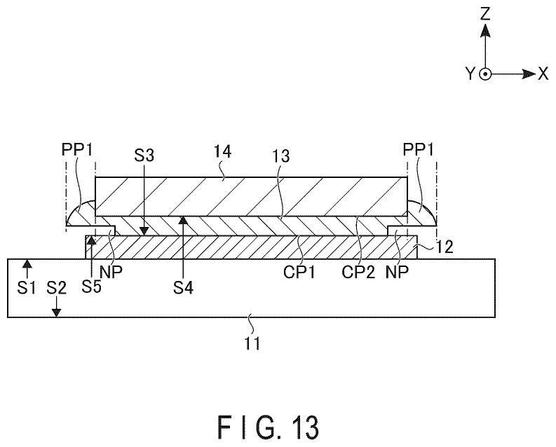

Next, as illustrated in FIG. 13, the insulating film 22 is removed (S107). The insulating film 22 is removed by, for example, a cleaning liquid. The insulating film 22 may be removed by heating.

With the configuration according to the present embodiment, the reliability of the semiconductor device 1 can be improved.

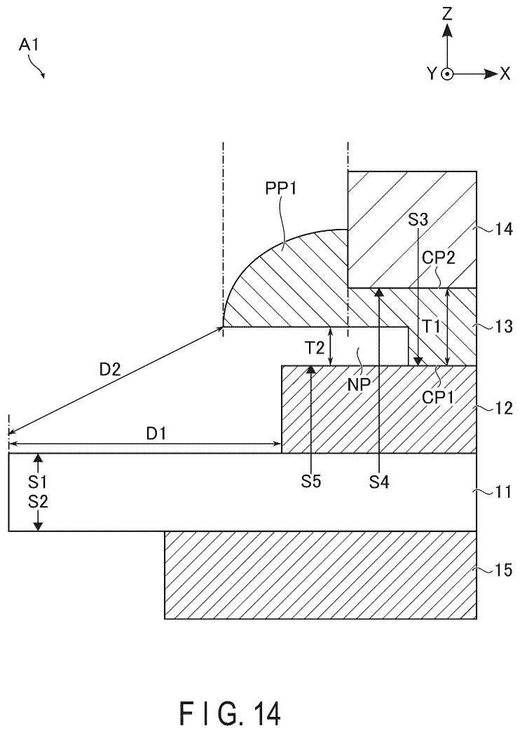

FIG. 14 is an enlarged cross-sectional view illustrating a part (region A1 in FIG. 5) of the structure of the semiconductor device 1.

In the chip 11, a range from the second electrode pad 15 to the end of the first surface S1 of the chip 11 is at the potential of the collector electrode. A range from the end of the first surface S1 of the chip 11 to the first electrode pad 12 is at the potential of the emitter electrode.

A relatively high voltage may be applied to the second electrode pad 15. In a case where a relatively high voltage is applied to the second electrode pad 15, and a distance D1 from the end of the first surface S1 of the chip 11 to the first electrode pad 12 is too short, creeping discharge between the emitter electrode and the collector electrode may occur, and a short circuit may occur between the second electrode pad 15 and the first electrode pad 12. Therefore, the distance D1 from the end of the first surface S1 of the chip 11 to the first electrode pad 12 is designed in consideration of creeping discharge. The distance D1 is, for example, about 2 mm.

Furthermore, in a case where the first conductive layer 14 to which the first bonding material 13 has been transferred is pressurized and sintered on the first electrode pad 12, the first bonding material 13 may project outward from the end surface of the first electrode pad 12, and the position of the end of the projecting portion PP1 of the first bonding material 13 in the Z direction may be the same as or lower than the third surface S3 of the first bonding material 13. In this case, a distance D2 from the end of the first surface S1 of the chip 11 to the end of the projecting portion PP1 is relatively short, and creeping discharge may occur in a case where a relatively high voltage is applied to the second electrode pad 15.

Therefore, in the present embodiment, before the pressurization and the sintering, the insulating film 22 is formed so as to cover the end surface of the first electrode pad 12, the end portion of the fifth surface S5 of the first electrode pad 12, and the part of the chip 11. As a result, in a case where the first conductive layer 14 to which the first bonding material 13 has been transferred is pressurized and sintered on the first electrode pad 12 and the insulating film 22, the contact portion CP1 and the notch portion NP surrounding the contact portion CP1 are formed on the third surface S3 of the first bonding material 13. The projecting portion PP1 of the first bonding material 13 is formed on the insulating film 22. As a result, the end of the contact portion CP1 is located inside the end surface of the first conductive layer 14. The end of the contact portion CP1 is located inside the end surface of the first electrode pad 12. The projecting portion PP1 of the first bonding material 13 is located above the first electrode pad 12 on the front surface side of the chip 11. Therefore, even after the insulating film 22 is removed, the distance D1 from the end of the first surface S1 of the chip 11 to the first electrode pad 12 can be secured. Furthermore, a relatively long distance can be secured as the distance D2 from the end of the first surface S1 of the chip 11 to the end of the projecting portion PP1. The distance D2 is, for example, about 1.5 mm. Therefore, according to the present embodiment, it is possible to suppress the occurrence of creeping discharge between the emitter electrode and the collector electrode. Therefore, it is possible to suppress the occurrence of a short circuit between the second electrode pad 15 and the first electrode pad 12. Thus, the reliability of the semiconductor device 1 can be improved.

In addition, since the end of the contact portion CP1 is located inside the end surface of the first conductive layer 14, the surface area of the first bonding material 13 is increased as compared with a case where the end of the contact portion CP1 is not located inside the end surface of the first conductive layer 14. Therefore, the heat dissipation of the first bonding material 13 is improved.

A relatively low voltage is applied to the third electrode pad 18. Therefore, as compared with creeping discharge between the emitter electrode and the collector electrode, there is a relatively low possibility that creeping discharge may occur between the emitter electrode and a gate electrode, but there is a possibility that creeping discharge may occur between the emitter electrode and the gate electrode.

In the present embodiment, as described above, the contact portion CP1 and the notch portion NP surrounding the contact portion CP1 are formed on the third surface S3 of the first bonding material 13. The projecting portion PP1 of the first bonding material 13 is formed on the insulating film 22. The end of the contact portion CP1 is located inside the end surface of the first conductive layer 14. The end of the contact portion CP1 is located inside the end surface of the first electrode pad 12. The projecting portion PP1 of the first bonding material 13 is located above the first electrode pad 12 on the front surface side of the chip 11. Furthermore, the third electrode pad 18 is spaced apart from the first electrode pad 12 and the first bonding material 13. Therefore, according to the present embodiment, it is possible to suppress the occurrence of creeping discharge between the emitter electrode and the gate electrode. Therefore, the occurrence of a short circuit between the third electrode pad 18 and the first electrode pad 12 can be suppressed. Thus, the reliability of the semiconductor device 1 can be improved.

### 1.3 Modification

A semiconductor device according to a modification of the first embodiment will be described. A method of manufacturing the semiconductor device 1 according to the modification of the first embodiment is different from that described in the first embodiment. In the following description, features different from those described in the first embodiment will be described.

### 1.3.1 Method of Manufacturing Semiconductor Device

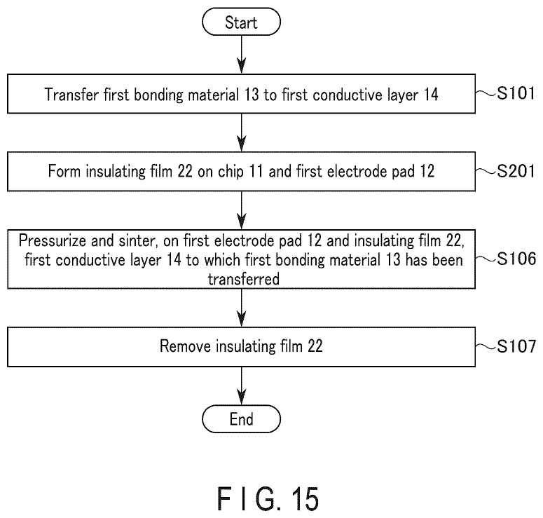

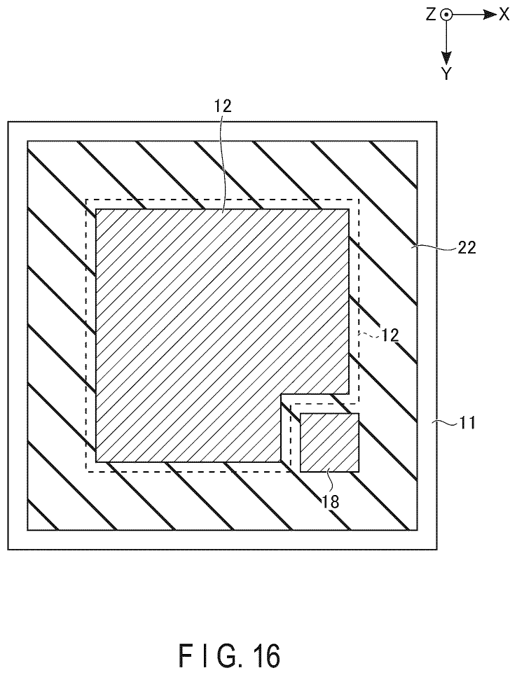

The method of manufacturing the semiconductor device 1 will be described with reference to FIGS. 15 and 16. FIG. 15 is a flowchart illustrating an example of the method of manufacturing the semiconductor device 1. FIG. 16 is a plan view illustrating an example of a structure in a process of manufacturing the semiconductor device 1. A process of forming the first electrode pad 12, the first bonding material 13, and the first conductive layer 14 on the first surface S1 of the chip 11 in the process of manufacturing the semiconductor device 1 will be described below. Therefore, in FIG. 16, illustration of the second electrode pad 15, the second bonding material 16, the second conductive layer 17, the first electrode 23, and the second electrode 24 is omitted.

In the method of manufacturing the semiconductor device 1 according to the modification of the first embodiment, steps S103 to S105 in FIG. 6 illustrated in the first embodiment are replaced with step S201. Step S201 will be described below.

After step S101 illustrated in FIG. 6 in the first embodiment is performed, the insulating film 22 is formed on the chip 11 and the first electrode pad 12 (S201). Specifically, the insulating film 22 is formed so as to cover the end surface of the first electrode pad 12, the end portion of the fifth surface S5 of the first electrode pad 12, and the part of the chip 11. The insulating film 22 is formed, for example, by coating using a dispenser. As illustrated in FIG. 16, the insulating film 22 is formed so as to cover the end portion of the first electrode pad 12 and the part of the chip 11 and to surround the first electrode pad 12 and a third electrode pad 18.

After step S201 is performed, steps S106 and S107 illustrated in FIG. 6 in the first embodiment are performed.

The semiconductor device 1 manufactured by the manufacturing method according to the present modification has a similar structure to that of the semiconductor device 1 manufactured by the manufacturing method according to the first embodiment. Therefore, according to the present modification, similarly to the first embodiment, the reliability of the semiconductor device 1 can be improved.

### 2. SECOND EMBODIMENT

A semiconductor device according to a second embodiment will be described. The semiconductor device 1 according to the second embodiment is different from that in the first embodiment in terms of a structure. A method of manufacturing the semiconductor device 1 according to the second embodiment is different from that in the first embodiment. In the following description, features different from those described in the first embodiment will be described.

### 2.1 Planar Structure of Semiconductor Device

A planar structure of the semiconductor device 1 will be described.

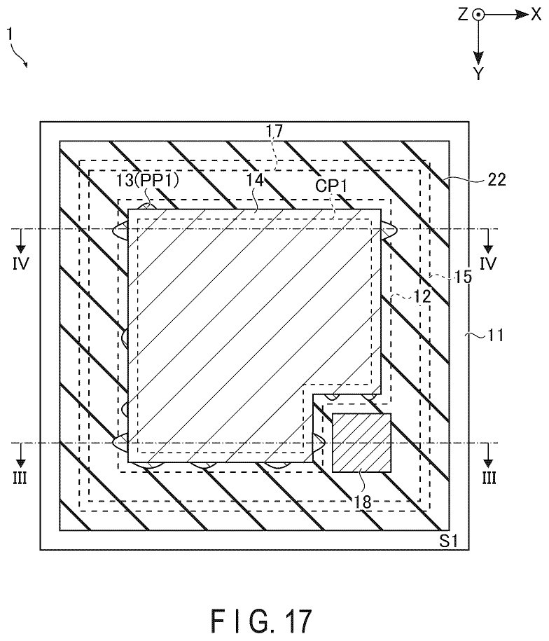

FIG. 17 is a plan view illustrating an example of the structure of the semiconductor device 1. FIG. 17 is a plan view of the semiconductor device 1 as viewed from a first surface S1 side of the chip 11. The chip 11, the first electrode pad 12, the first bonding material 13, the first conductive layer 14, and the third electrode pad 18 are indicated by solid lines. The second electrode pad 15 and the second conductive layer 17 are indicated by broken lines. In FIG. 17, illustration of the first electrode 23 and the second electrode 24 is omitted.

As illustrated in FIG. 17, the semiconductor device 1 further includes the insulating film 22 in addition to the configuration illustrated in FIG. 4 in the first embodiment. The insulating film 22 covers the end portion of the first electrode pad 12 and the part of the chip 11, and surrounds the first electrode pad 12 and the third electrode pad 18.

### 2.2 Cross-Sectional Structure of Semiconductor Device

A cross-sectional structure of the semiconductor device 1 will be described.

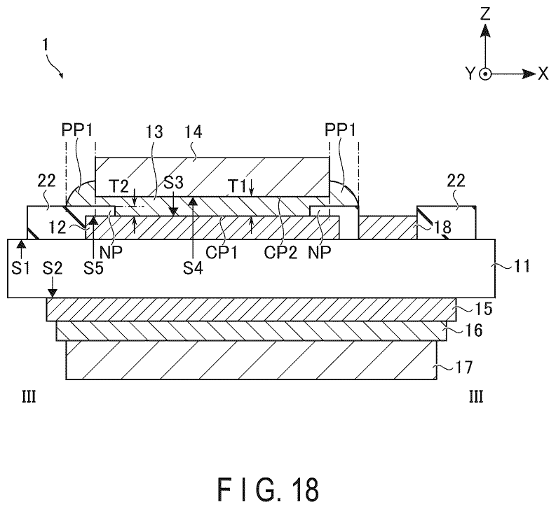

FIG. 18 is a cross-sectional view taken along line III-III in FIG. 17, illustrating an example of the structure of the semiconductor device 1. In FIG. 18, illustration of the first electrode 23 and the second electrode 24 is omitted.

As illustrated in FIG. 18, the insulating film 22 is embedded in the notch portion NP of the third surface S3 of the first bonding material 13. The insulating film 22 covers the end surface of the first electrode pad 12, the end portion of the fifth surface S5 of the first electrode pad 12, and the part of the chip 11. That is, the first electrode pad 12 is surrounded by the insulating film 22. The third electrode pad 18 is surrounded by the insulating film 22.

A projecting portion PPI of the first bonding material 13 is provided on the insulating film 22.

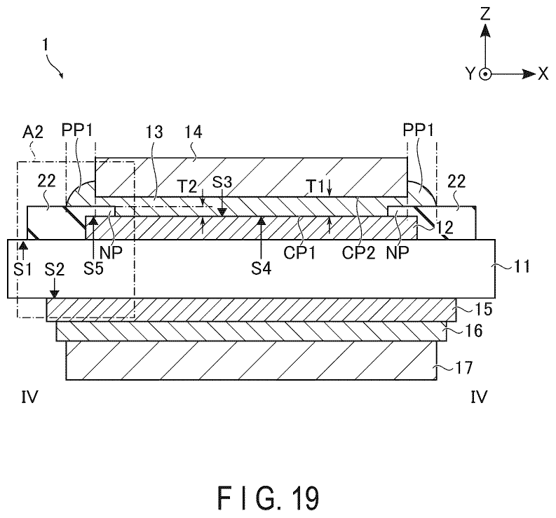

FIG. 19 is a cross-sectional view taken along line IV-IV in FIG. 17, illustrating an example of the structure of the semiconductor device 1. In FIG. 19, illustration of the first electrode 23 and the second electrode 24 is omitted.

As illustrated in FIG. 19, the insulating film 22 is embedded in the notch portion NP of the third surface S3 of the first bonding material 13. The insulating film 22 covers the end surface of the first electrode pad 12, the end portion of the fifth surface S5 of the first electrode pad 12, and the part of the chip 11. That is, the first electrode pad 12 is surrounded by the insulating film 22.

The projecting portion PP1 of the first bonding material 13 is provided on the insulating film 22.

### 2.3 Method of Manufacturing Semiconductor Device

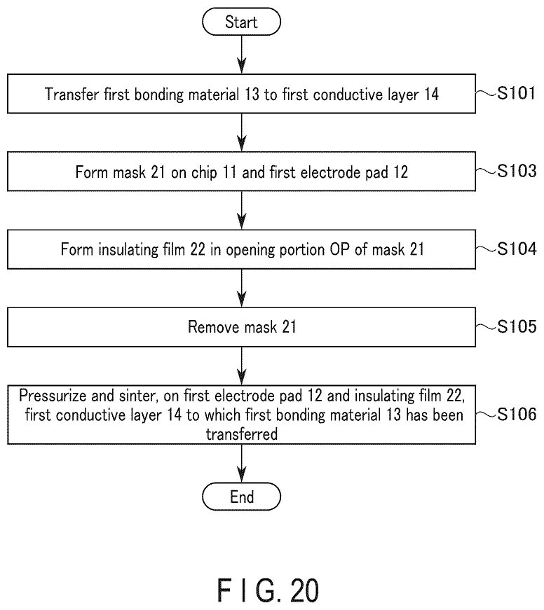

The method of manufacturing the semiconductor device 1 will be described with reference to FIG. 20. FIG. 20 is a flowchart illustrating an example of the method of manufacturing the semiconductor device 1.

In the method of manufacturing the semiconductor device 1 according to the second embodiment, step S107 illustrated in FIG. 6 in the first embodiment is removed. As a result, the contact portion CP1 and the notch portion NP are formed on the third surface S3 of the first bonding material 13 after step S106 illustrated in FIG. 6 in the first embodiment is performed. The projecting portion PP1 of the first bonding material 13 is formed on the insulating film 22. Furthermore, the insulating film 22 remains between the end of the first surface S1 of the chip 11 and the first electrode pad 12 and between the end of the first surface S1 of the chip 11 and the end of the projecting portion PP1 of the first bonding material 13.

Note that steps S103 to S105 illustrated in FIG. 20 may be replaced with step S201 illustrated in FIG. 15 in the modification of the first embodiment.

According to the present embodiment, the reliability of the semiconductor device 1 can be improved.

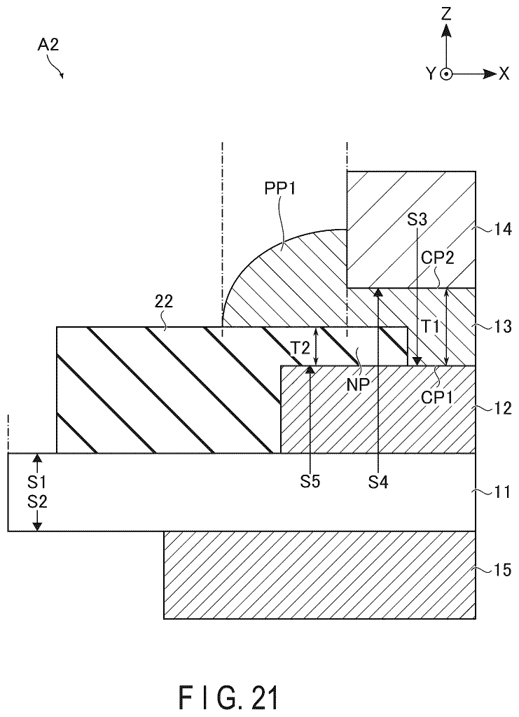

FIG. 21 is an enlarged cross-sectional view illustrating a part (region A2 in FIG. 19) of the structure of the semiconductor device 1.

In the present embodiment, as in the first embodiment, the first conductive layer 14 to which the first bonding material 13 has been transferred is pressurized and sintered on the first electrode pad 12 and the insulating film 22. Thereafter, the insulating film 22 is not removed. As a result, as illustrated in FIG. 21, the insulating film 22 remains between the end of the first surface S1 of the chip 11 and the first electrode pad 12 and between the end of the first surface S1 of the chip 11 and the end of the projecting portion PP1 of the first bonding material 13. Therefore, according to the present embodiment, it is possible to suppress the occurrence of creeping discharge between the emitter electrode and the collector electrode. Accordingly, similarly to the first embodiment, the reliability of the semiconductor device 1 can be improved.

In the present embodiment, the insulating film 22 also remains between the first electrode pad 12 and the third electrode pad 18. Therefore, according to the present embodiment, it is possible to suppress the occurrence of creeping discharge between the emitter electrode and the gate electrode. Accordingly, similarly to the first embodiment, the reliability of the semiconductor device 1 can be improved.

### 3. MODIFICATIONS AND THE LIKE

As described above, a semiconductor device (1) according to an embodiment includes a chip (11) having a first surface (S1) and a second surface (S2) opposite to the first surface, a first electrode pad (12) provided on the first surface (S1) of the chip (11), a first conductive layer (14) provided above the first electrode pad (12), a first bonding material (13) that is provided between the first electrode pad (12) and the first conductive layer (14) and is in contact with the first electrode pad (12) and the first conductive layer (14), and a second electrode pad (15) provided on the second surface (S2) of the chip (11). A third surface (S3) of the first bonding material (13) facing the first electrode pad (12) has a contact portion (CP1) in contact with the first electrode pad (12) and a notch portion (NP) surrounding the contact portion. An end of the contact portion (CP1) is located inside an end surface of the first conductive layer (14).

Note that the embodiments are not limited to the above-described embodiments, and various modifications are possible.

In addition, in the flowcharts described above in the embodiments, the order of the processing can be changed as much as possible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a chip having a first surface and a second surface opposite to the first surface;
a first electrode pad provided on the first surface of the chip;
a first conductive layer provided above the first electrode pad;
a first bonding material that is provided between the first electrode pad and the first conductive layer and is in contact with the first electrode pad and the first conductive layer; and
a second electrode pad provided on the second surface of the chip,
wherein a third surface of the first bonding material facing the first electrode pad has a contact portion in contact with the first electrode pad and a notch portion surrounding the contact portion, and
an end of the contact portion is located inside an end surface of the first conductive layer.

2. The device according to claim 1, wherein the first bonding material has a projecting portion which projects outward from the end surface of the first conductive layer.

3. The device according to claim 2, wherein the projecting portion is in contact with a part of the end surface of the first conductive layer.

4. The device according to claim 1, wherein the end of the contact portion is further located inside an end surface of the first electrode pad.

5. The device according to claim 2, wherein the projecting portion is located above the first electrode pad.

6. The device according to claim 1, wherein a thickness of the first bonding material at the contact portion is 5 μm to 80 μm.

7. The device according to claim 1, wherein a thickness of the notch portion is less than or equal to ½ of a thickness of the first bonding material at the contact portion.

8. The device according to claim 1, wherein the first bonding material includes any of gold, silver, copper, lead, tin, and nickel.

9. The device according to claim 1, wherein the first conductive layer includes any of molybdenum, ruthenium, tungsten, iron, gold, silver, copper, cobalt, nickel, and palladium.

10. The device according to claim 1, further comprising:
an insulating film embedded in the notch portion and covering an end surface of the first electrode pad, an end portion of a fourth surface of the first electrode pad, and a part of the chip.

11. The device according to claim 10, wherein the first bonding material has a projecting portion which projects outward from the end surface of the first conductive layer, and
the projecting portion is provided on the insulating film.

12. A method of manufacturing a semiconductor device, comprising:
transferring a first bonding material to a first conductive layer;
forming a first electrode pad on a surface of a chip;
forming an insulating film so as to cover an end surface of the first electrode pad, an end portion of a first surface of the first electrode pad opposite to the chip, and a part of the chip; and
pressurizing and sintering, on the first electrode pad and the insulating film, the first conductive layer to which the first bonding material has been transferred.

13. The method according to claim 12, further comprising:
removing the insulating film after the pressurizing and the sintering.
